(19) United States
(12) Patent Application Publication
(10) Pub. No.: US 2025/0062160 A1
(43) Pub. Date: Feb. 20, 2025

(54) METAL IMPLANTATION TO BARRIER OR LINER FOR INTERCONNECT

(71) Applicant: Applied Materials, Inc., Santa Clara, CA (US)

(72) Inventors: Ge QU, Sunnyvale, CA (US); Zhiyuan WU, San Jose, CA (US); Jiajie CEN, Santa Clara, CA (US); Feng CHEN, San Jose, CA (US); Kevin KASHEFI, Dublin, CA (US); Chengyu LIU, Sunnyvale, CA (US)

(21) Appl. No.: 18/749,589

(22) Filed: Jun. 20, 2024

Related U.S. Application Data
(60) Provisional application No. 63/532,465, filed on Aug. 14, 2023.

(51) Int. Cl. H01L 21/768; H01L 21/02

(52) U.S. Cl. CPC H01L 21/76867; H01L 21/02068; H01L 21/76846; H01L 21/76879

(57) ABSTRACT

A method of forming a metal interconnect in a semiconductor structure includes performing a barrier layer deposition process to deposit a barrier layer within an opening formed through a dielectric layer, performing a liner deposition process to deposit a liner layer on the barrier layer, performing a metal treatment process to implant metal dopants into a surface of the liner layer, and performing a gap fill process to form a metal interconnect on the metal treated surface of the liner layer within the opening.

### CROSS-REFERENCE TO RELATED APPLICATIONS

This application claims priority to U.S. Provisional Application Ser. No. 63/532,465 filed Aug. 14, 2023, which is herein incorporated by reference in its entirety.

### BACKGROUND

### Field

Embodiments of the present disclosure generally relate to fabrication of metal interconnects, and more particularly, to metal treatment of an underlying barrier layer and an underlying liner layer.

### Description of the Related Art

In silicon integrated circuits and microchips, copper interconnects are used to reduce propagation delays and power consumption. In fabricating copper interconnects, a barrier layer and a liner layer are deposited in trenches and/or vias patterned in an underlying dielectric and metal layer, and the trenches and/or vias are filled and reflowed with copper. A barrier layer prevents copper from diffusing into the dielectric layer. A liner layer enhances the adhesion between the copper interconnect and the barrier layer. Fabrication of copper interconnects faces gap-fill and high resistance issues when scaled down to sub-10 nm critical dimension (CD). Due to the minimum thickness requirement of a barrier layer (e.g. 1 nm) and a liner (e.g. 2 nm), a device CD for copper interconnects shrinks, leading to reduced interface to volume ratio. Thus, resistivity is increased due to increased electron scattering at the interfaces, and device reliability is reduced due to reduced adhesion between the copper interconnect and the surrounding dielectric layer.

Therefore, there is a need for methods for fabricating interconnects that promotes adhesion between interconnects with surrounding materials.

### SUMMARY

Embodiments of the present disclosure provide a method of forming a metal interconnect in a semiconductor structure. The method includes performing a barrier layer deposition process to deposit a barrier layer within an opening formed through a dielectric layer, performing a liner deposition process to deposit a liner layer on the barrier layer, performing a metal treatment process to implant metal dopants into a surface of the liner layer, and performing a gap fill process to form a metal interconnect on the metal treated surface of the liner layer within the opening.

Embodiments of the present disclosure provide a method of forming a metal interconnect in a semiconductor structure. The method includes performing a barrier-liner layer deposition process to deposit a barrier-liner layer within an opening formed through a dielectric layer, performing a metal treatment process to implant metal dopants into a surface of the barrier-liner layer, and performing a gap fill process to form a metal interconnect on the metal treated surface of the barrier-liner layer within the opening.

Embodiments of the present disclosure provide a method of forming a metal interconnect in a semiconductor structure. The method includes performing a barrier layer deposition process to deposit a barrier layer within an opening formed through a dielectric layer, performing a first metal treatment process to implant first metal dopants into a surface of the barrier layer, performing a liner deposition process to deposit a liner layer on the barrier layer, performing a second metal treatment process to implant second metal dopants into a surface of the liner layer, and performing a gap fill process to form a metal interconnect on the metal treated surface of the liner layer within the opening.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of an exemplary substrate processing system, according to one or more embodiments.

FIG. 2 is a schematic view of an exemplary physical vapor deposition (PVD) chamber, according to one or more embodiments.

FIG. 3 is a cross-sectional view of a portion of a process kit, according to one or more embodiments.

FIG. 4 depicts a process diagram of a method of forming a metal interconnect in a semiconductor structure, according to one or more embodiments.

FIGS. 5A, 5B, 5C, and 5D are cross-sectional views of a portion of the semiconductor structure corresponding to various states of the method of FIG. 4.

FIG. 6 depicts a process diagram of a method of forming a metal interconnect in a semiconductor structure, according to one or more embodiments.

FIGS. 7A, 7B, and 7C are cross-sectional views of a portion of the semiconductor structure corresponding to various states of the method of FIG. 6.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments of the disclosure provided herein generally relate to fabrication of metal interconnects (e.g., copper (Cu)). More particularly, embodiments described herein provide methods for plasma assisted implantation of metal dopants into an underlying liner layer (e.g., cobalt (Co) or ruthenium (Ru)) and/or an underlying barrier layer (e.g., tantalum (Ta), titanium (Ti), tantalum nitride (TaN), titanium nitride (TiN)) to improve adhesion of the metal interconnects with the liner layer and/or the barrier layer. The implantation of metal dopants (e.g., copper (Cu)) into a barrier layer and/or a liner layer may disrupt interface composition of the barrier layer and/or the liner layer and promotes adhesion of the metal interconnect to the liner layer and/or the barrier layer, which may reduce liner agglomeration and improve gap fill capability, and thus increases device reliability and suppresses interface electron scattering.

### Exemplary Substrate Processing System

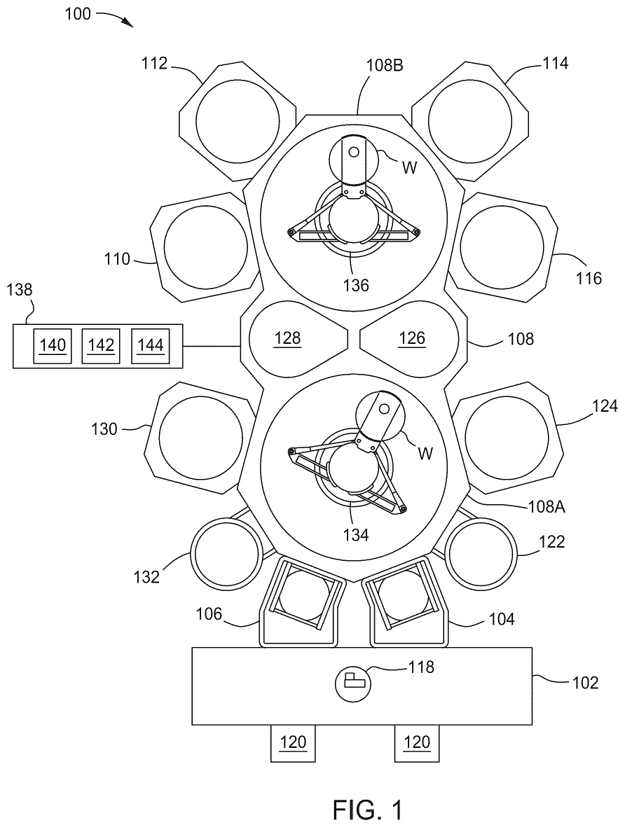

FIG. 1 is a schematic top view of an exemplary substrate processing system 100, according to one or more embodiments. The processing system 100 generally includes an equipment front-end module (EFEM) 102 for loading substrates into the processing system 100, a first load lock chamber 104 and a second load lock chamber 106 coupled to the EFEM 102, a transfer chamber 108 coupled to the first load lock chamber 104, and processing chambers 110, 112, 114, and 116 coupled to the transfer chamber 108. The EFEM 102 generally includes one or more robots 118 that are configured to transfer substrates from one or more front opening unified pods (FOUPs) 120 to at least one of the first load lock chamber 104 or the second load lock chamber 106. Proceeding counterclockwise around the transfer chamber 108 from a buffer portion 108A of the transfer chamber 108, the processing system 100 includes the first load lock chamber 104, the second load lock chamber 106, processing chambers 122, 124, pass-through chambers 126, 128, and processing chambers 130, 132. The buffer portion 108A of the transfer chamber 108 includes a first robot 134 that is configured to transfer substrates to each of the chambers 104, 106, 122, 124, 126, 128, 130, 132.

A back-end portion 108B of the transfer chamber 108 of the includes a second robot 136 that is configured to transfer substrates W to each of the pass-through chambers 126, 128 and the processing chambers 110, 112, 114, and 116 coupled to the back-end portion 108B of the processing system 100. In general, the processing chamber 122 can be a degas chamber, the processing chamber 132 is a pre-clean chamber, and the processing chambers 110, 112, 114, 116, 124, 130 can include at least one of an atomic layer deposition (ALD) chamber, a chemical vapor deposition (CVD) chamber, a physical vapor deposition (PVD) chamber, an etch chamber, a degas chamber, an anneal chamber, and other type of semiconductor substrate processing chamber.

The buffer portion 108A and the back-end portion 108B of the transfer chamber 108 and each chamber coupled to the transfer chamber 108 are maintained at a vacuum state. As used herein, the term “vacuum” may refer to pressures less than 760 Torr, and will typically be maintained at pressures near 10⁻⁵ Torr (i.e., ˜10⁻³ Pa). However, some high-vacuum systems may operate below near 10⁻⁷ Torr (i.e., ˜10⁻⁵ Pa). In certain embodiments, the vacuum is created using a rough pump (not shown) and/or a turbomolecular pump (not shown) coupled to the transfer chamber 108 and to each of the chambers. However, other types of vacuum pumps are also contemplated.

A system controller 138, such as a programmable computer, is coupled to the processing system 100 for controlling one or more of the components therein. In operation, the system controller 138 enables data acquisition and feedback from the respective components to coordinate processing in the processing system 100.

The system controller 138 includes a programmable central processing unit (CPU) 140, which is operable with a memory 142 (e.g., non-volatile memory) and support circuits 144. The support circuits 144 (e.g., cache, clock circuits, input/output subsystems, power supplies, etc., and combinations thereof) are conventionally coupled to the CPU 140 and coupled to the various components within the processing system 100.

In some embodiments, the CPU 140 is one of any form of general purpose computer processor used in an industrial setting, such as a programmable logic controller (PLC), for controlling various monitoring system component and sub-processors. The memory 142, coupled to the CPU 140, is non-transitory and is typically one or more of readily available memory such as random access memory (RAM), read only memory (ROM), floppy disk drive, hard disk, or any other form of digital storage, local or remote.

Herein, the memory 142 is in the form of a computer-readable storage media containing instructions (e.g., non-volatile memory), that when executed by the CPU 140, facilitates the operation of the processing system 100. The instructions in the memory 142 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored, and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

### Processing Chamber Examples

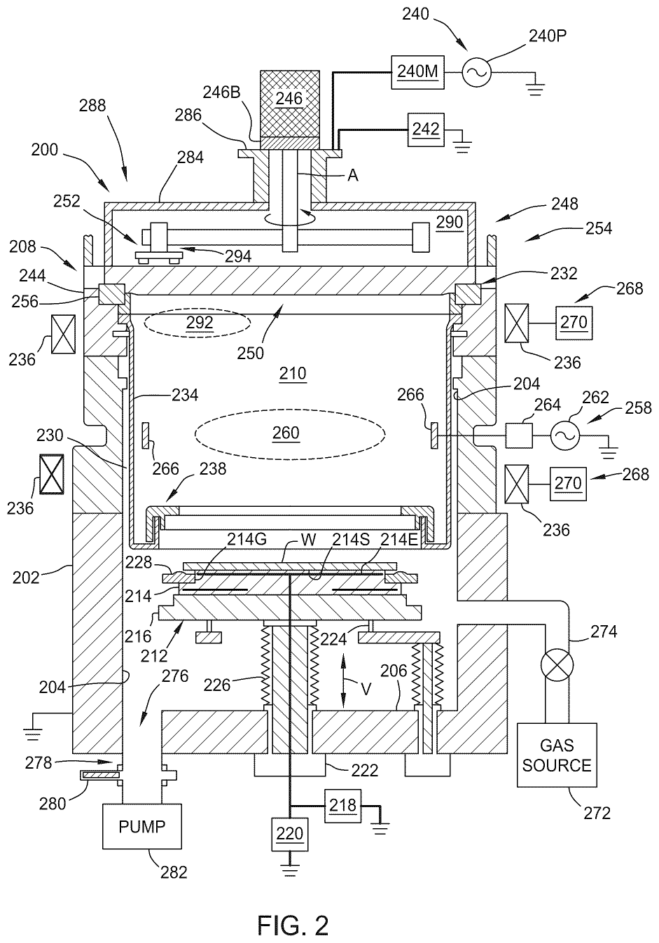

FIG. 2 is a schematic view of an exemplary physical vapor deposition (PVD) chamber 200 that can be the processing chamber 110, 112, 114, or 116 of the processing system 100 shown in FIG. 1.

The processing chamber 200 includes a chamber body 202 having sidewalls 204, a bottom wall 206, and an upper process assembly 208 that enclose a processing region 210 or plasma zone. The chamber body 202 is typically fabricated from welded plates of stainless steel or a unitary block of aluminum. The sidewalls 204 may be formed of aluminum and the bottom wall 206 may be formed of a stainless steel plate. The sidewalls 204 generally contain a slit valve (not shown) to provide entry and egress of a substrate W from the processing chamber 200.

The processing chamber 200 further includes a pedestal assembly 212 that generally includes a substrate support 214 sealingly coupled to a platform housing 216. The substrate support 214 may be formed of aluminum or ceramic. The substrate support 214 has a substrate receiving surface 214S that receives and supports the substrate W during processing, and a peripheral edge 214G that terminates before an overhanging edge of the substrate W. The substrate support 214 may be an electrostatic chuck, a ceramic body, a heater or a combination thereof. In one embodiment, the substrate support 214 is an electrostatic chuck that includes a dielectric body having an electrode 214E, embedded therein. The dielectric body is typically fabricated from a high thermal conductivity dielectric material such as pyrolytic boron nitride, aluminum nitride, silicon nitride, alumina or an equivalent material. In one embodiment, the electrode 214E is configured so that when a DC voltage is applied to the electrode 214E, by an electrostatic chuck power supply 218, a substrate W disposed on the substrate receiving surface 214S will be electrostatically chucked thereto to improve the heat transfer between the substrate W and the substrate support 214. In another embodiment, an impedance controller 220 is also coupled to the electrode 214E so that a voltage can be maintained on the substrate W during processing to affect the plasma interaction with the surface of the substrate W. The platform housing 216 is typically fabricated from a metallic material such as stainless steel or aluminum. A cooling plate (not shown) is generally disposed within the platform housing 216 to thermally regulate the substrate support 214.

The pedestal assembly 212 is supported from the bottom wall 206 by a lift mechanism 222, which is configured to move the pedestal assembly 212 between an upper processing position and a lower transfer position. Additionally, in the lower transfer position, lift pins 224 are moved through the pedestal assembly 212 to position the substrate W a distance from the pedestal assembly 212 to facilitate the exchange of the substrate W with a substrate transfer mechanism disposed exterior to the processing chamber 200, such as a single blade robot (not shown). A bellows 226 is typically disposed between the pedestal assembly 212 and the bottom wall 206 to isolate the processing region 210 from the interior of the pedestal assembly 212 and the exterior of the processing chamber 200. The pedestal assembly 212 supports a deposition ring 228 along with the substrate W during processing.

The processing chamber 200 further includes a process kit 230 that includes various components easily removable from the processing chamber 200, for example, to clean sputtering deposits off the component surfaces, replace or repair eroded components, or to adapt the processing chamber 200 for other processes. The process kit 230 further includes an isolator ring assembly 232, a grounded shield 234, and lower magnetic coil assemblies 236.

Components in the upper process assembly 208 of the processing chamber 200 in cooperation with the grounded shield 234, the pedestal assembly 212, and a cover ring 238 confine the plasma formed in the processing region 210 to the region above the substrate W.

The upper process assembly 208 includes a radio frequency (RF) source 240, a direct current (DC) source 242, an adaptor 244, a motor 246, and a lid assembly 248. The lid assembly 248 generally includes a target 250, a magnetron system 252 and a lid enclosure 254. The upper process assembly 208 is supported by the sidewalls 204 when in a closed position, as shown in FIG. 2. A ceramic target isolator 256 is disposed between the isolator ring assembly 232, the target 250, and the adaptor 244 to prevent vacuum leakage therebetween. The adaptor 244 is sealably coupled to the sidewalls 204, and is configured to help with the removal of the upper process assembly 208 and isolator ring assembly 232.

When in the processing position, the target 250 is disposed adjacent to the adaptor 244, and is exposed to the processing region 210. The target 250 contains material that is deposited on the substrate W during a PVD, or sputtering process. The isolator ring assembly 232 is disposed between the target 250 and the grounded shield 234 and the chamber body 202 to electrically isolate the target 250 from the grounded shield 234 and the chamber body 202.

During processing, the target 250 is biased relative to a grounded region of the processing chamber 200 (e.g., the chamber body 202 and the adaptor 244) by a power source disposed in the RF source 240 and/or the DC source 242. In one embodiment, the RF source 240 includes an RF power source 240P and an RF match 240M that are configured to efficiently deliver RF energy to the target 250. In one example, the RF power source 240A is capable of generating RF currents at a frequency of between about 13.56 MHz and about 228 MHz at powers between about 0 and about 5 kWatts. In one example, the DC source 242 is capable of delivering between about 0 and about 10 kWatts of DC power.

The central portion of the processing chamber 200 includes an inductive coil assembly 258 that is positioned within a central region of the process kit 230, and is configured to form an inductively coupled plasma 260 during processing that is used to ionize atoms ejected from the target 250 and/or ionize process gases during processing. The inductive coil assembly 258 includes an RF power source 262 and an impedance match 264 that are coupled to a coil 266 that is disposed within the processing region 210 of the processing chamber 200. In some embodiments, the coil 266 includes a single turn coil that is formed from a metal. In one configuration, the coil 266 is formed from a conductive material that is made of the same material as the target 250. In some configurations, the RF power source 262 is capable of generating RF currents at a frequency of between about 13.56 MHz and about 228 MHz at powers between about 0 and about 5 kWatts.

In some embodiments, the central portion of the processing chamber 200 also includes one or more electromagnet assemblies 268. The electromagnet assemblies 268 each include a current source 270 that is configured to bias the magnetic coil assemblies 236, respectively. The one or more electromagnet assemblies are positioned adjacent to the central region of the process kit 230, and are each configured to provide a generated magnetic field within the processing region 210 to help alter and/or shape the radial distribution of the plasma formed with the processing region 210 during processing. In some configurations, the current source 270 is capable of generating a DC or RF current or voltage at a power between about 0 and about 5 kWatts.

During processing, a gas, such as argon, is supplied to the processing region 210 from a gas source 272 via conduits 274. The gas source 272 may include process gas, such as argon (Ar), helium (He), neon (Ne), krypton (Kr), nitrogen (N₂), hydrogen (H₂), which is capable of energetically impinging upon and sputtering material from the target 250. The gas source 272 may also include a reactive gas, such as one or more of an oxygen-containing gas or a nitrogen-containing gas, which is capable of reacting with the sputtering material to form a layer on a substrate. Spent process gas and byproducts are exhausted from the processing chamber 200 through exhaust ports 276 that receive spent process gas and direct the spent process gas to an exhaust conduit 278 having an adjustable position gate valve 280 to control the pressure in the processing region 210 in the processing chamber 200. The exhaust conduit 278 is connected to one or more exhaust pump 282, such as a cryopump. Typically, the pressure of the sputtering gas in the processing chamber 200 during processing is set to sub-atmospheric levels, such as a vacuum environment, for example, a pressure of about 0.6 mTorr to about 400 mTorr. In one embodiment, the processing pressure is set to about 20 mTorr to about 100 mTorr. A plasma is formed between the substrate W and the target 250 from the gas. Ions within the plasma are accelerated toward the target 250 and cause material to become dislodged from the target 250. The dislodged target material is deposited on the substrate.

The lid enclosure 254 generally includes a conductive wall 284, a center feed 286 and a shielding 288. In this configuration, the conductive wall 284, the center feed 286, the target 250 and a portion of the motor 246 enclose and form a back region 290. The back region 290 is a sealed region disposed on the back side of the target 250 and is generally filled with a flowing liquid to remove the heat generated at the target 250 during processing. In one embodiment, the conductive wall 284 and the center feed 286 are configured to support the motor 246 and the magnetron system 252, so that the motor 246 can rotate the magnetron system 252 during processing. In one embodiment the motor 246 is electrically isolated from the RF or DC power delivered from the power supplies by use of a dielectric layer 246B, such as Delrin, G10, or Ardel.

The shielding 288 may include one or more dielectric materials that are positioned to enclose and prevent the RF energy delivered to the target 250 from interfering with and affecting other processing chambers disposed in the processing system (shown in FIG. 1). In one configuration, the shielding 288 may be formed of a Delrin, G10, Ardel or other similar material and/or a thin grounded sheet metal RF shield.

To provide efficient sputtering, the magnetron system 252 is positioned in back of the target 250 in the upper process assembly 208 to create a magnetic field in the processing region 210 adjacent a sputtering surface 250S of the target 250, which creates a magnetron-induced plasma 292. The magnetic field by magnetron system 252 is created to trap electrons and ions to thereby increase the plasma density in the magnetron-induced plasma 292 region and to thereby also increase the sputtering rate. According to one embodiment of the disclosure, the magnetron system 252 includes a source magnetron assembly 294 that includes an outer pole (not shown) and an inner pole (not shown). The magnetron system 252 is rotated about a central axis A by use of the motor 246. In some embodiments, a “closed loop” magnetron configuration is formed within the magnetron system 252 such that the outer pole of the magnetron surrounds the inner pole of the magnetron forming a gap between the poles that is a continuous loop. In the closed loop configuration, the magnetic fields that emerge and reenter through a surface of the target form a “closed loop” pattern can be used to confine electrons near the surface of the target in a closed pattern, which is often called a “racetrack” type pattern. A closed loop, as opposed to the open-loop, magnetron configuration is able to confine electrons and generate a high density plasma near the sputtering surface 250S of the target 250 to increase the sputtering yield. In some other embodiments, an “open loop” magnetron configuration is formed within the magnetron system 252 such that the outer pole of the magnetron surrounds the inner pole of the magnetron forming a gap between the poles that is a continuous loop. In an open loop magnetron configuration, the electrons trapped between the inner and outer poles will migrate, leak out and escape from the B-fields created at open ends of the magnetron, thus only holding the electrons for a short period of time during the sputtering process due to the reduced confinement of the electrons. It has been found that the use of an open loop magnetron configuration, can provide significant step coverage improvements and provide an improved material composition uniformity across the substrate surface, when used in conjunction with the RF and DC sputtering of multi-compositional targets described herein.

In some embodiments, the impedance controller 220 is replaced by an RF source (not shown) and an impedance match (not shown) that are coupled to the electrode 214E. In some embodiments, the RF power source is capable of generating RF currents at a frequency of between about 13.56 MHz and about 228 MHz at powers between about 0 and about 5 kWatts.

A program (or computer instructions) readable by a system controller, such as the system controller 138 shown in FIG. 1, determines which tasks are performable on a substrate. Preferably, the program is software readable by the system controller 138 that includes code to perform tasks relating to monitoring, execution and control of the movement and various process recipe tasks and recipe steps being performed in the processing system 100. For example, the system controller 138 can include program code that includes a substrate positioning instruction set to operate the pedestal assembly 212, a gas flow control instruction set to operate gas flow control valves to set a flow of sputtering gas to the processing chamber 200, a gas pressure control instruction set to operate a throttle valve or gate valve to maintain a pressure in the processing chamber 200, a temperature control instruction set to control a temperature control system (not shown) in the pedestal assembly 212 or sidewalls 204 to set temperatures of the substrate W or sidewalls 204, respectively, and a process monitoring instruction set to monitor the process in the processing chamber 200.

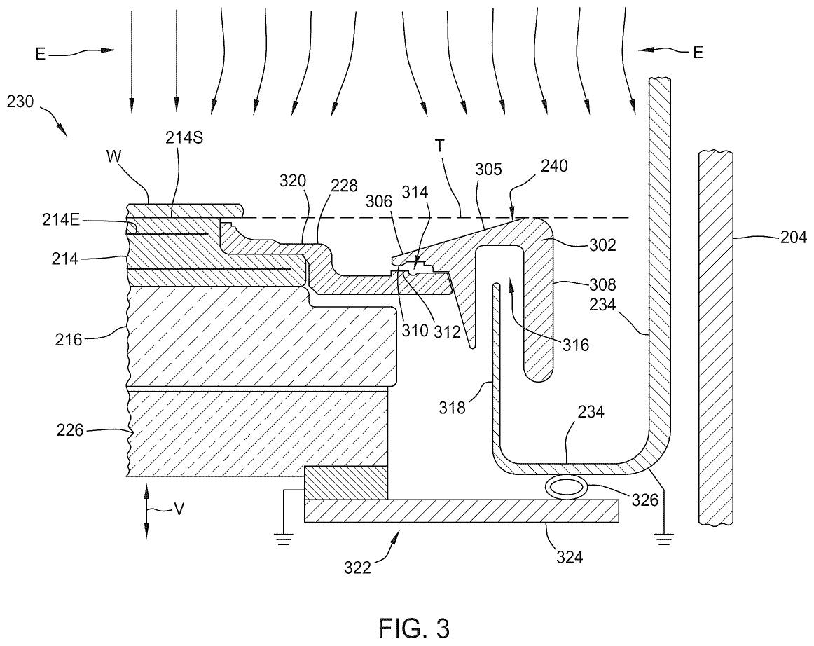

FIG. 3 is a cross-sectional view of a portion of the process kit 230, according to one or more embodiments. The deposition ring 228 is generally formed in an annular shape, or annular band, surrounding the substrate support 214. During processing, the deposition ring 228 and the cover ring 238 cooperate with one another to reduce formation of sputter deposits on peripheral edges of the substrate support 214 and an overhanging edge of the substrate W.

The cover ring 238 encircles and at least partially covers the deposition ring 228 to receive, and thus, shadow the deposition ring 228 from the bulk of the sputtering deposits. The cover ring 238 is fabricated from a material that can resist erosion by the sputtering plasma, for example, a metallic material such as stainless steel, titanium or aluminum, or a ceramic material, such as aluminum oxide. In one embodiment, the cover ring 238 is formed from a stainless steel material. In one embodiment, a surface of the cover ring 238 is treated with a twin-wire aluminum arc-spray coating, such as, for example, CLEANCOAT™, to reduce particle shedding from the surface of the cover ring 238. In one embodiment, the deposition ring 228 is fabricated from a dielectric material that can resist erosion by the sputtering plasma, for example, a ceramic material, such as aluminum oxide.

The cover ring 238 comprises an annular ring 302 comprising a top surface 304 that is sloped radially inwards and encircles the substrate support 214. The top surface 304 of the annular ring 302 has an inner periphery 306 and an outer periphery 308. The inner periphery 306 comprises a projecting brim 310 which overlies the radially inward dip comprising an open inner channel of the deposition ring 228. The projecting brim 310 reduces deposition of sputtering deposits on the open inner channel disposed between the surface 312 of the deposition ring 228 and the projecting brim 310. The projecting brim 310 is sized, shaped, and positioned to cooperate with and complement the arc-shaped gap 314 to form a convoluted and constricted flow path between the cover ring 238 and deposition ring 228 that inhibits the flow of process deposits onto the substrate support 214 and the platform housing 216.

The top surface 304 may be inclined at an angle of between about 10 degrees and about 20 degrees from the horizontal. The angle of the top surface 304 of the cover ring 238 is designed to minimize the buildup of sputter deposits nearest to the overhanging edge of the substrate W, which would otherwise negatively impact the particle performance obtained across the substrate W. The cover ring 238 may comprise any material that is compatible with process chemistries such as titanium or stainless steel. In one embodiment, the cover ring 238 has an outer diameter that is between about 15.5 inches (39.4 cm) and about 16 inches (40.6 cm). In one embodiment, the cover ring 238 has a height between about 1 inch (2.5 cm) and about 1.5 inches (3.8 cm).

The space or gap 316 between the ring support portion 318 of the grounded shield 234 and the cover ring 238 forms a convoluted S-shaped pathway or labyrinth for plasma to travel. The shape of the pathway is advantageous, for example, because it hinders and impedes ingress of plasma species into this region, reducing undesirable deposition of sputtered material.

In one embodiment, as shown in FIG. 3, the cover ring 238 is designed and positioned relative to the grounded shield 234 during processing, so that will not be in contact with the grounded shield 234, and thus will electrically “float”. Further, in one embodiment, it is desirable to position the cover ring 238 and the deposition ring 228 so that they are a distance from the substrate W and below the substrate receiving surface 214S of the substrate support 214 to allow the electric field “E” created by the delivery of RF and/or DC power to the target 250 to be more uniform across the surface of the substrate during processing. It is believed that electrically floating surfaces, such as the surfaces of the cover ring 238 will be subject to electron bombardment during various parts of the delivered RF power's half-cycle, thus affecting the uniformity of the RF electric field in a region near an edge of the substrate W. Bombardment is believed to occur when the RF potential from the RF power source 240P at the top surface 304 is more positive than the average DC potential formed at the top surface 304. Therefore, in one embodiment, it is desirable to assure that the deposited film layer formed on the upper surfaces of the cover ring 238 does not have an electric path to ground and that it is disposed a distance away from the edge of the substrate W. In one example, the inner periphery 306 of the cover ring 238 is disposed a distance of at least 0.5 inches (12.7 mm) from the edge of the substrate W. In another example, the inner periphery 306 of the cover ring 238 is disposed a distance of between about 0.5 inches (12.7 mm) and about 3 inches (76.2 mm), such as about 1 inch (25.4 mm) from the edge of the substrate W.

In one embodiment, the cover ring 238 and the deposition ring 228 are positioned below the substrate receiving surface 214S (e.g., extension line “T”) by about 0.2 inches (5 mm)

In one embodiment, the pedestal assembly 212 further comprises a pedestal grounding assembly 322 that is adapted to assure that the bellows 226 are grounded during processing. If the bellows 226 achieve a different RF potential than the grounded shield 234 it can affect the plasma uniformity and cause arcing to occur in the processing chamber, which will affect the deposited film layer's properties, generate particles and/or affect the process uniformity. In one embodiment, the pedestal grounding assembly 322 comprises a plate 324 that contains a conductive spring 326. The conductive spring 326 and plate 324 are configured to make electrical contact with a surface of the grounded shield 234 when the pedestal assembly 212 is moved to the processing position (shown in FIG. 3) in a direction “V” by the lift mechanism 222. The conductive spring 326 may disengage from the grounded shield 234 when the pedestal assembly 212 is moved to the transfer position (shown in FIG. 1A) in a direction “V” by the lift mechanism 222.

It is to be understood that the methods described herein can be carried out in a PVD chamber in other embodiments. For example, in some other embodiments of a PVD chamber 200, there is no coil and a spacing between the target 250 and the substrate support 214 is smaller than that shown in FIG. 2.

### Processing Methods

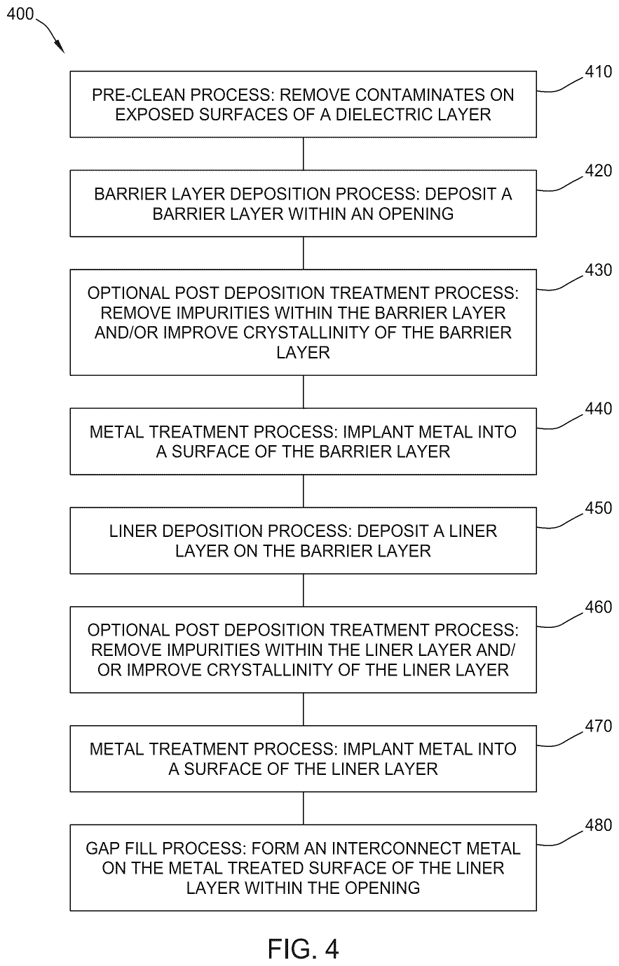

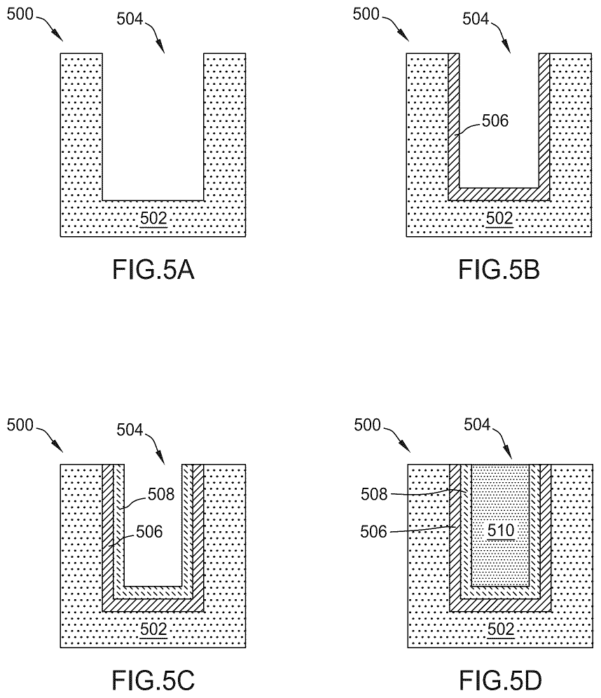

FIG. 4 depicts a process diagram of a method 400 of forming a metal interconnect in a semiconductor structure 500, according to one or more embodiments of the present disclosure. FIGS. 5A, 5B, 5C, and 5D are cross-sectional views of a portion of the semiconductor structure 500 corresponding to various states of the method 400. It should be understood that FIGS. 5A, 5B, 5C, and 5D illustrate only partial schematic views of the semiconductor structure 500, and the semiconductor structure 500 may contain any number of transistor sections and additional materials having aspects as illustrated in the figures. It should also be noted that although the method illustrated in FIG. 4 is described sequentially, other process sequences that include one or more operations that have been omitted and/or added, and/or has been rearranged in another desirable order, fall within the scope of the embodiments of the disclosure provided herein.

As shown in FIG. 5A, the semiconductor structure 500 includes a dielectric layer 502 patterned with an opening (e.g., a trench) 504 through the dielectric layer 502 on a substrate (not shown). The dielectric layer 502 may be formed of silicon oxide (SiO₂) or a low-k dielectric material, such as carbon-containing silicon oxides (SiOC), such as Black Diamond® dielectric film available from Applied Materials, Inc., or other low-k polymers, such as polyamides. In some embodiments, a metal layer (not shown) tungsten (W) or copper (Cu) is formed at the bottom of the opening 504. The opening 504 may have a critical dimension (CD) of less than about 10 nm.

The substrate may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate may have various dimensions, such as 200 mm, 300 mm or 450 mm diameter wafers, as well as, rectangular or square panels. Unless otherwise noted, embodiments and examples described herein are conducted on substrates with a 300 mm diameter or a 450 mm diameter.

The method 400 begins with block 410, in which a pre-clean process is performed to remove contaminates on exposed inner surfaces of the opening 504 (i.e., the dielectric layer 502 and the metal layer formed at the bottom of the opening 504). The pre-clean process may include etching the inner surfaces of the opening 504 by a remote plasma assisted chemical etch process using H₂/Ar gas performed in a processing chamber, such as Aktiv™ Preclean (APC) chamber available from Applied Materials of Santa Clara, Calif., or a capacitively coupled plasma (CCP) chemical etch process with ion bombardment using H₂/Ar gas performed in a processing chamber, such as Preclean XT chamber available from Applied Materials of Santa Clara, Calif. The pre-clean process may be performed in a pre-clean chamber, such as the processing chamber 132 shown in FIG. 1.

In block 420, a barrier layer deposition process is performed to deposit a barrier layer 506 within the opening 504, as shown in FIG. 5B. The barrier layer 506 may be formed of transition metal such as tantalum (Ta) or titanium (Ti), and nitrides thereof, such as tantalum nitride (TaN) or titanium nitride (TiN), and deposited by an atomic layer deposition (ALD) or other suitable deposition process, performed in a processing chamber, such as the processing chambers 110, 112, 114, or 116. The barrier layer 506 may have a thickness of greater than about 1 nm to prevent electron migration from a metal interconnect to be formed within the opening 504.

In block 430, an optional post deposition treatment process is performed to remove impurities within the barrier layer 506 and/or improve crystallinity of the barrier layer 506.

The post deposition treatment process may include a plasma pre-treatment process in which the barrier layer 506 is exposed to a plasma formed from a process gas including hydrogen (H₂)-containing gas. The plasma pre-treatment process may be a capacitively coupled plasma (CCP) process performed in the same processing chamber as the processing chamber in which the barrier layer deposition process in block 420 is performed.

In block 440, an optional metal treatment process is performed to implant metal dopants, such as copper (Cu), cobalt (Co), manganese (Mn), ruthenium (Ru), titanium (Ti), tantalum (Ta), tungsten (W), molybdenum (Mo), or alloys thereof, into a surface of the barrier layer 506. The metal treated surface of the barrier layer 506 may have a depth of between about 5 Å and 10 Å, corresponding to 2 and 3 monolayers.

The metal implantation process is performed in a PVD chamber, such as the processing chamber 200 shown in FIG. 2, by directing ions of metal such dopants, as copper (Cu), cobalt (Co), manganese (Mn), ruthenium (Ru), titanium (Ti), tantalum (Ta), tungsten (W), molybdenum (Mo), or alloys thereof, ejected from a target, such as the target 250 shown in FIG. 2, to the surface of the barrier layer 506. During the metal implantation process, process gas, such as argon (Ar), helium (He), neon (Ne), krypton (Kr), nitrogen (N₂), hydrogen (H₂) is supplied and pressure in the processing chamber is set to about 0.1 mTorr to about 100 mTorr, for example, about 3 mTorr, about 10 m Torr, or about 30 mTorr. The target is biased relative to a ground region of the processing chamber by a source power supply, such as the RF source 240 and/or the DC source 242 shown in FIG. 1, at powers between about 100 Watts and about 2000 Watts, for example, about 250 Watts. A substrate support, such as the substrate support 214, is kept at a temperature of between about 15° C. and about 400° C., for example, at room temperature or at about 25° C. A time duration of the metal treatment process is between about 0.2 seconds and about 10 seconds, for example, about 1.5 seconds and about 5 seconds.

During the metal treatment process, an inductively coupled plasma (e.g., the inductively coupled plasma 260 in FIG. 2) is formed to sputter material from the target and perform gas etching and ion implantation by biasing an RF coil (e.g., the coil 266 in FIG. 2) by an RF power source (e.g., the RF power source 262 in FIG. 2) at an RF power of between about 100 Watts and about 2000 Watts, for example, about 250 Watts and a bias power of between about 0 Watts and about 500 Watts, for example, between about 50 Watts and about 125 Watts.

In block 450, a liner deposition process to deposit a liner layer 508 on the barrier layer 506, as shown in FIG. 5C. The liner layer 508 may be formed of cobalt (Co) or ruthenium (Ru), and deposited by chemical vapor deposition (CVD), physical vapor deposition (PVD), or other suitable deposition process, performed in a processing chamber, such as the processing chambers 110, 112, 114, or 116. The liner layer 508 may have a thickness of greater than about 2 nm, to promote the subsequent gap fill to form a metal interconnect within the opening 504.

In block 460, an optional post deposition treatment process is performed to remove impurities within the liner layer 508 and/or improve crystallinity of the liner layer 508. The post deposition treatment process in block 460 is similar to or the same as the post deposition treatment process in block 430.

In block 470, a metal treatment process is performed to implant metal dopants, such as copper (Cu), cobalt (Co), manganese (Mn), ruthenium (Ru), titanium (Ti), tantalum (Ta), tungsten (W), molybdenum (Mo), or alloys thereof, into a surface of the liner layer 508. The metal treated surface of the liner layer 508 may have a depth of between about 5 Å and 10 Å, corresponding to 2 and 3 monolayers. The metal treatment process in block 470 is similar to or the same as the metal treatment process in block 440.

In block 480, a gap fill process is performed to form a metal interconnect 510 on the metal treated surface of the liner layer 508 within the opening 504, as shown in FIG. 5D. The gap fill process may include depositing a metal seed layer on the metal treated surface of the liner layer 508 within the opening 504, by physical vapor deposition (PVD), chemical vapor deposition (CVD), or other suitable deposition process and subsequently thickening the metal seed layer to completely fill the opening 504 during a reflow anneal. The metal interconnect 510 may include copper (Cu), a copper (Cu) alloy, aluminum (AI), an aluminum (Al) alloy, tungsten (W), a tungsten (W) alloy, molybdenum (Mo), or a molybdenum (Mo) alloy.

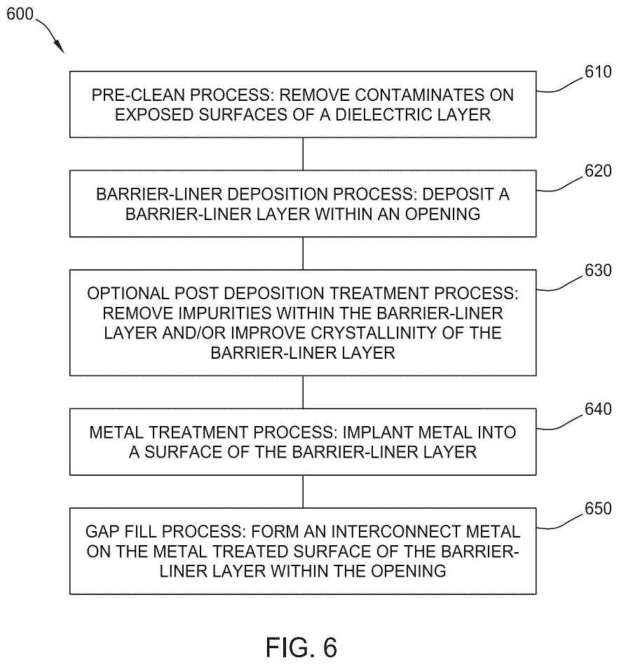

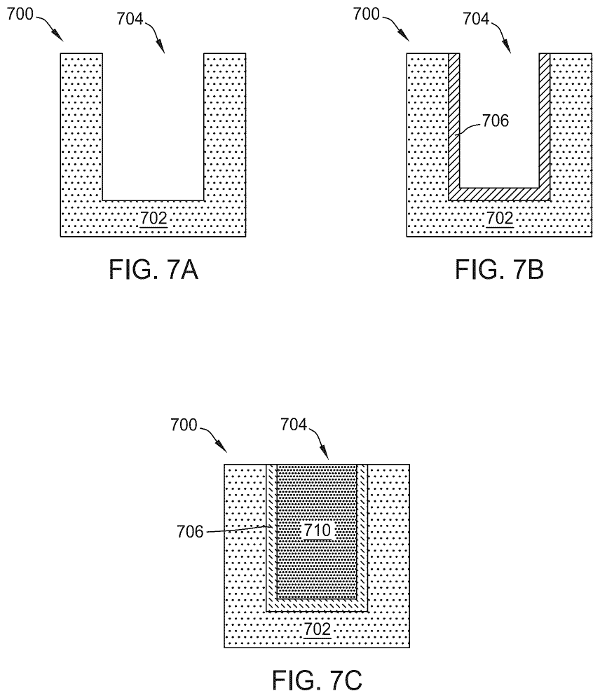

FIG. 6 depicts a process diagram of a method 600 of forming a metal interconnect in a semiconductor structure 700, according to one or more embodiments of the present disclosure. FIGS. 7A, 7B, and 7C are cross-sectional views of a portion of the semiconductor structure 700 corresponding to various states of the method 600. It should be understood that FIGS. 7A, 7B, and 7C illustrate only partial schematic views of the semiconductor structure 500, and the semiconductor structure 500 may contain any number of transistor sections and additional materials having aspects as illustrated in the figures. It should also be noted that although the method illustrated in FIG. 6 is described sequentially, other process sequences that include one or more operations that have been omitted and/or added, and/or has been rearranged in another desirable order, fall within the scope of the embodiments of the disclosure provided herein.

As shown in FIG. 7A, the semiconductor structure 500 includes a dielectric layer 702 patterned with an opening (e.g., a trench) 704 through the dielectric layer 702 on a substrate (not shown). The dielectric layer 702 may be formed of silicon oxide (SiO₂) or a low-k dielectric material, such as carbon-containing silicon oxides (SiOC), such as Black Diamond® dielectric film available from Applied Materials, Inc., or other low-k polymers, such as polyamides. In some embodiments, a metal layer (not shown) tungsten (W) or copper (Cu) is formed at the bottom of the opening 704. The opening 704 may have a critical dimension (CD) of less than about 10 nm.

The method 600 begins with block 610, in which a pre-clean process is performed to remove contaminates on exposed inner surfaces of the opening 704 (i.e., the dielectric layer 702 and the metal layer formed at the bottom of the opening 704). The pre-clean process may include etching the inner surfaces of the opening 704 by a remote plasma assisted chemical etch process using H₂/Ar gas performed in a processing chamber, such as Aktiv™ Preclean (APC) chamber available from Applied Materials of Santa Clara, Calif., or a capacitively coupled plasma (CCP) chemical etch process with ion bombardment using H₂/Ar gas performed in a processing chamber, such as Preclean XT chamber available from Applied Materials of Santa Clara, Calif. The pre-clean process may be performed in a pre-clean chamber, such as the processing chamber 132 shown in FIG. 1.

In block 620, a barrier-liner deposition process is performed to deposit a barrier-liner layer 706 within the opening 704, as shown in FIG. 7B. The barrier-liner layer 706 may be formed of tantalum (Ta), titanium (Ti), or nitrides thereof, such as tantalum nitride (TaN) or titanium nitride (TiN), cobalt (Co), ruthenium (Ru), tungsten (W), molybdenum (Mo), or in stack, or alloys thereof, and deposited by an atomic layer deposition (ALD) or other suitable deposition process, performed in a processing chamber, such as the processing chambers 110, 112, 114, or 116. The barrier-liner layer 706 may have a thickness of between about 5 Å and about 30 Å, or between about 10 Å and 20 Å to prevent electron migration from a metal interconnect to be formed within the opening 704 and promote the subsequent gap fill to form a metal interconnect within the opening 704.

In block 630, an optional post deposition treatment process is performed to remove impurities within the barrier-liner layer 706 and/or improve crystallinity of the barrier-liner layer 706. The post deposition treatment process in block 630 is similar to or the same as the post deposition treatment process in block 430.

In block 640, a metal treatment process is performed to implant metal dopants, such as copper (Cu), cobalt (Co), manganese (Mn), ruthenium (Ru), titanium (Ti), tantalum (Ta), tungsten (W), molybdenum (Mo), or alloys thereof, into a surface of the liner layer 508. The metal treated surface of the barrier-liner layer 706 may have a depth of between about 5 Å and 10 Å, corresponding to 2 and 3 monolayers. The metal treatment process in block 640 is similar to or the same as the metal treatment process in block 440.

In block 650, a gap fill process is performed to form a metal interconnect 710 on the metal treated surface of the barrier-liner layer 706 within the opening 704, as shown in FIG. 7C. The gap fill process in block 650 is similar to or the same as the gap fill process in block 480.

### EXAMPLES

The inventors have discovered that a metal treatment of a liner layer (e.g., implanting copper (Cu) into a surface of a liner layer) as shown in block 470 of the method 400 improves resistivity and/or adhesion of the liner layer to copper (Cu). As shown below in details, a metal treatment of implanting copper (Cu) into a cobalt (Co) liner layer reduces resistivity, and a metal treatment of implanting copper (Cu) into a ruthenium (Ru) liner layer improves adhesion of the liner layer to copper (Cu) to be deposited on the liner layer.

Resistivity and thickness of a cobalt (Co) liner layer were measured with and without a metal treatment. The liner layer was treated by plasma to remove impurities after the deposition as a baseline process. A metal treatment was performed under two conditions: (i) with a liner layer having thickness of about 10 Å, etching about 0.5 Å from a surface of the liner layer, and (ii) with a liner layer having thickness of about 13 Å, etching about 3 Å from a surface of the liner layer. In the baseline case (iii), a liner layer was formed but no metal treatment was performed. Under similar film thickness, Co liner in the cases (i) and (ii) has resistivity improvement compared to the baseline case (iii).

Sheet resistance of Co liner was measured as a function of a total thickness. In the cases (i) and (ii), sheet resistance is lower than the baseline case (iii). In the case (iv), where the post plasma treatment process was performed after the metal treatment under the condition (ii), sheet resistance is further decreased form that in case (i) and (ii).

Resistivity and thickness of a ruthenium (Ru) liner layer were measured with and without a metal treatment. The liner layer was treated by plasma to remove impurities after the deposition as a baseline process. A metal treatment was performed under two conditions: (i) with a liner layer having thickness of about 10 Å, etching about 0.5 Å from a surface of the liner layer, and (ii) with a liner layer having thickness of about 13 Å, etching about 3 Å from a surface of the liner layer. In the baseline case (iii), a liner layer was formed but no metal treatment was performed. A slight resistivity decrease was observed in the case (i) as compared the baseline case (iii). In the case (ii), resistivity was about the same as the baseline case (iii), but a total thickness of a Ru liner layer and a bulk Ru liner layer is less than the baseline case (iii). Thus, resistivity is lowered for the same thickness.

Sheet resistance of Ru liner was measured as a function of total thickness. Resistivity increase as annealing time increases is less in the case (i) as compared to the baseline case (iii). This result indicates better adhesion between copper (Cu) and a metal treated surface of a Ru liner layer.

In the embodiments described herein, the methods of fabrication of metal interconnects (e.g., copper (Cu)) are provided. The methods include plasma assisted implantation of metal dopants into an underlying liner layer (e.g., cobalt (Co) or ruthenium (Ru)) and/or an underlying barrier layer (e.g., tantalum (Ta), titanium (Ti), tantalum nitride (TaN), titanium nitride (TiN)) to improve adhesion of the metal interconnects with the liner layer and/or the barrier layer. The implantation of metal dopants (e.g., copper (Cu)) into a barrier layer and/or a liner layer may disrupt interface composition of the barrier layer and/or the liner layer and promotes adhesion of the metal interconnect to the liner layer and/or the barrier layer, which may reduce liner agglomeration and improve gap fill capability, and thus increases device reliability and suppresses interface electron scattering.

While the foregoing is directed to embodiments of the present disclosure, other and further embodiments of the disclosure may be devised without departing from the basic scope thereof, and the scope thereof is determined by the claims that follow.

What is claimed is:

1. A method of forming a metal interconnect in a semiconductor structure, comprising:
performing a barrier layer deposition process to deposit a barrier layer within an opening formed through a dielectric layer;
performing a liner deposition process to deposit a liner layer on the barrier layer;
performing a metal treatment process to implant metal dopants into a surface of the liner layer; and
performing a gap fill process to form a metal interconnect on the metal treated surface of the liner layer within the opening.

2. The method of claim 1, wherein the metal dopants comprise material selected from the group consisting of copper (Cu), cobalt (Co), manganese (Mn), ruthenium (Ru), titanium (Ti), tantalum (Ta), tungsten (W), molybdenum (Mo), and alloys thereof.

3. The method of claim 1, wherein
the metal interconnect comprises material selected from the group consisting of copper (Cu), a copper (Cu) alloy, aluminum (AI), an aluminum (Al) alloy, tungsten (W), a tungsten (W) alloy, molybdenum (Mo), and a molybdenum (Mo) alloy.

4. The method of claim 1, wherein the barrier layer comprises material selected from the group consisting of tantalum (Ta), titanium (Ti), and nitrides thereof.

5. The method of claim 1, further comprising:
prior to the metal treatment process, performing a post deposition treatment process to remove impurities within the liner layer.

6. The method of claim 1, further comprising:
prior to the barrier layer deposition process, performing a pre-clean process to remove contaminants formed on an exposed inner surface of the opening.

7. The method of claim 1, wherein the liner layer comprises material selected from cobalt (Co) or ruthenium (Ru).

8. A method of forming a metal interconnect in a semiconductor structure, comprising:
performing a barrier-liner layer deposition process to deposit a barrier-liner layer within an opening formed through a dielectric layer;
performing a metal treatment process to implant metal dopants into a surface of the barrier-liner layer; and
performing a gap fill process to form a metal interconnect on the metal treated surface of the barrier-liner layer within the opening.

9. The method of claim 8, wherein
the metal interconnect comprises material selected from the group consisting of copper (Cu), a copper (Cu) alloy, aluminum (AI), an aluminum (Al) alloy, tungsten (W), a tungsten (W) alloy, molybdenum (Mo), and a molybdenum (Mo) alloy, and
the metal dopants comprise material selected from the group consisting of copper (Cu), cobalt (Co), manganese (Mn), ruthenium (Ru), titanium (Ti), tantalum (Ta), tungsten (W), molybdenum (Mo), and alloys thereof.

10. The method of claim 8, wherein the barrier-liner layer comprises material selected from the group consisting of tantalum (Ta), titanium (Ti), and nitrides thereof, cobalt (Co), ruthenium (Ru), tungsten (W), molybdenum (Mo), and alloys thereof.

11. The method of claim 8, further comprising:
prior to the metal treatment process, performing a post deposition treatment process to remove impurities within the barrier-liner layer.

12. The method of claim 11, further comprising:
prior to the barrier layer deposition process, performing a pre-clean process to remove contaminants formed on an exposed inner surface of the opening.

13. A method of forming a metal interconnect in a semiconductor structure, comprising:
performing a barrier layer deposition process to deposit a barrier layer within an opening formed through a dielectric layer;
performing a first metal treatment process to implant first metal dopants into a surface of the barrier layer;
performing a liner deposition process to deposit a liner layer on the barrier layer;
performing a second metal treatment process to implant second metal dopants into a surface of the liner layer; and
performing a gap fill process to form a metal interconnect on the metal treated surface of the liner layer within the opening.

14. The method of claim 13, wherein
the metal interconnect comprises material selected from the group consisting of copper (Cu), a copper (Cu) alloy, aluminum (AI), an aluminum (Al) alloy, tungsten (W), a tungsten (W) alloy, molybdenum (Mo), and a molybdenum (Mo) alloy, and
the first metal dopants and the second metal dopants comprise material selected from the group consisting of copper (Cu), cobalt (Co), manganese (Mn), ruthenium (Ru), titanium (Ti), tantalum (Ta), tungsten (W), molybdenum (Mo), and alloys thereof.

15. The method of claim 13, wherein the barrier layer comprises material selected from the group consisting of tantalum (Ta), titanium (Ti), and nitrides thereof.

16. The method of claim 13, further comprising:
prior to the first metal treatment process, performing a first post deposition treatment process to remove impurities within the barrier layer.

17. The method of claim 16, further comprising:
prior to the second metal treatment process, performing a second post deposition treatment process to remove impurities within the liner layer.

18. The method of claim 17, wherein the first and second post deposition treatment processes each comprise a capacitively coupled plasma (CCP) process.

19. The method of claim 13, further comprising:
prior to the barrier layer deposition process, performing a pre-clean process to remove contaminants formed on an exposed surface of the dielectric layer.

20. The method of claim 13, wherein the liner layer comprises material selected from cobalt (Co) or ruthenium (Ru).
